(19) United States
(12) Patent Application Publication
(10) Pub. No.: US 2020/0194604 A1
(43) Pub. Date: Jun. 18, 2020

(54) LIGHT COLLECTION AND PHOTOVOLTAIC MEMBER COMBINATION ASSEMBLY

(71) Applicant: Marc Lyn Sundermeyer, Montrose, SD (US)

(72) Inventor: Marc Lyn Sundermeyer, Montrose, SD (US)

(21) Appl. No.: 16/223,972

(22) Filed: Dec. 18, 2018

(51) Int. Cl. H01L 31/054; H01L 31/048

(52) U.S. Cl. CPC H01L 31/054; H01L 31/048

(57) ABSTRACT

A light collection and photovoltaic member combination assembly includes a plate is comprised of a transparent material. The plate has a front side, a back side, and a peripheral edge, wherein the peripheral edge includes an upper edge and a lower edge. A photovoltaic material is positioned against each of the front and back sides. The photovoltaic material is spaced from the upper edge on each of the front and back sides to define a free portion of the plate extending from the photovoltaic material to the upper edge. The free portion is configured to receive light and direct the light to the photovoltaic material.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

### (2) Description of Related Art Including Information Disclosed Under 37 CFR 1.97 and 1.98

The disclosure and prior art relates to photovoltaic cell and light collector combinations and more particularly pertains to a new photovoltaic cell and light collector combination for producing a larger amount of electricity using a smaller footprint of surface area by using vertically orientated photovoltaic cells which have light directed toward them. This orientation allows for laterally aligning the photovoltaic cells such that multiple photovoltaic cells are positioned within a smaller area than when the photovoltaic cells are placed in a conventional horizontal orientation.

### BRIEF SUMMARY OF THE INVENTION

An embodiment of the disclosure meets the needs presented above by generally comprising a first panel and a second panel. Each of the first and second panels has a first side, a second side, and a perimeter edge. The first and second panels are aligned with each other such that first sides of the panels face each other. A receiving space is defined between the first and second panels. A photovoltaic material is positioned on the first sides of each of the panels. A plate is comprised of a transparent material and the receiving space has the plate positioned therein. The plate extends outwardly in at least one direction from the receiving space to define a free portion of the plate. The free portion is configured to receive light and direct the light into the receiving space such that the light strikes the photovoltaic material.

In another embodiment, a plate is comprised of a transparent material. The plate has a front side, a back side, and a peripheral edge, wherein the peripheral edge includes an upper edge and a lower edge. A photovoltaic material is positioned against each of the front and back sides. The photovoltaic material is spaced from the upper edge on each of the front and back sides to define a free portion of the plate extending from the photovoltaic material to the upper edge. The free portion is configured to receive light and direct the light to the photovoltaic material.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a front isometric view of a light collection and photovoltaic member combination assembly according to an embodiment of the disclosure.

FIG. 2 is a side view of an embodiment of the disclosure.

FIG. 3 is a cross-sectional view of an embodiment of the disclosure taken along line 3-3 of FIG. 1.

FIG. 4 is a rear isometric view of an embodiment of the disclosure.

FIG. 5 is a front isometric view of an embodiment of the disclosure.

FIG. 6 is a front isometric view of an embodiment of the disclosure.

### DETAILED DESCRIPTION OF THE INVENTION

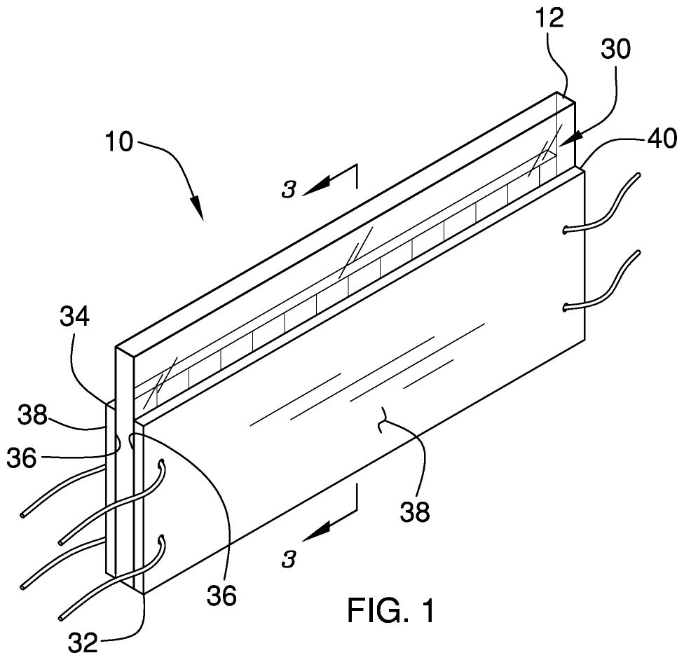

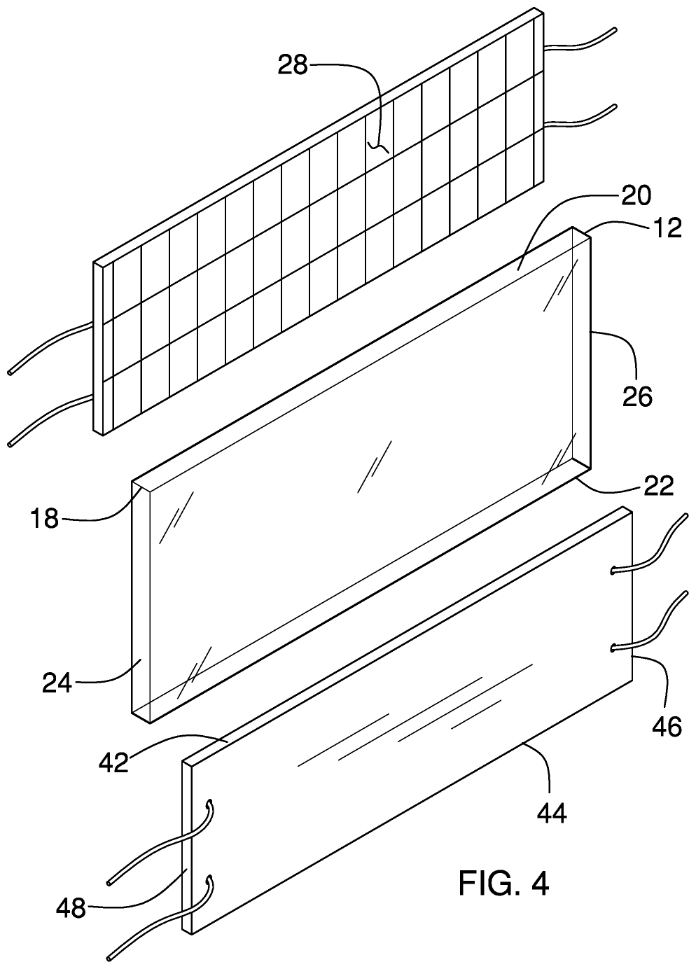

With reference now to the drawings, and in particular to FIGS. 1 through 6 thereof, a new photovoltaic cell and light collector combination embodying the principles and concepts of an embodiment of the disclosure and generally designated by the reference numeral 10 will be described.

As best illustrated in FIGS. 1 through 6, the light collection and photovoltaic member combination assembly 10 generally comprises a plate 12 which is comprised of a transparent material. While the term transparent is being used, it should be understood that the material may be considered translucent as it would have a transmittance percentage of less than 100%. Essentially, the material must facilitate the transmission of light through the plate 12 and have a transmittance of greater than 80% in the wavelengths of light required by photovoltaic materials to be used with the assembly 10. Furthermore, the plate 12 may be constructed of material such that deflection of particular light waves is deflected more or less depending on the efficiencies of photovoltaic materials, such as solar cells, which are used with the assembly. Generally, the material used for constructing the plate 12 may include plastics, glass, crystalline materials and the like.

In one embodiment, the assembly includes the plate 12 having a front side 14, a back side 16, and a peripheral edge 18. The peripheral edge 18 includes an upper edge 20 and a lower edge 22, as well as a first lateral edge 24 and a second lateral edge 26. The size of the panel 12 may vary depending on the embodiment of the assembly 10 constructed.

A photovoltaic material 28 is positioned against each of the front 14 and back 16 sides and may comprise any conventional photovoltaic construction used to convert light into electricity. As such, it may comprise, for example, photovoltaic cells, photovoltaic printing onto the plate 12, or photovoltaic spray applied to the plate 12. The photovoltaic material 28 is spaced from the upper edge 20 on each of the front 14 and back 16 sides to define a free portion 30 of the plate 12, which extends from the photovoltaic material 28 to the upper edge 20.

The free portion 30 is configured to receive light and direct the light to the photovoltaic material 28. Specifically, the free portion 30, as it is not covered by the photovoltaic material 28, is exposed to light from the sun, or from some other light source, so that the light travels toward the lower edge 22 and between the front 14 and back 16 sides. As the light propagates through the plate 12, it will travel outwardly through the front 14 and back 16 sides, striking the photovoltaic material 28 to generate electricity.

With respect to the above, it should be understood that the orientation of the photovoltaic material 28 is orientated perpendicular to what would normally be a conventional orientation of photovoltaic cells. Typically, conventional photovoltaic cells will lie flat against a roof surface or will be angled to increase the amount of sunlight available to the photovoltaic cells. However, with the current assembly 10, the photovoltaic material 28 will typically lie in vertically orientated planes so that light is able to strike the plate 12 from multiple directions and move down the plate 12 and strike across the photovoltaic material 28. Because the orientation is vertical as opposed to horizontal, or near horizontal, the surface area covered by the photovoltaic material 28 compared to the photovoltaic material 28 provided is much lower than horizontally orientated photovoltaic cells. However, the plate 12 allows the photovoltaic material 28 to receive light without need for the photovoltaic material 28 to be directed at the source of the light. Far more photovoltaic material 28 surface are may therefore be utilized on a smaller footprint that would be possible with conventional photovoltaic cell configurations.

The photovoltaic material may further extend from the first lateral edge 24 to the second lateral edge 26 and to the lower edge 22. This positioning will provide as much as light receptive area as possible.

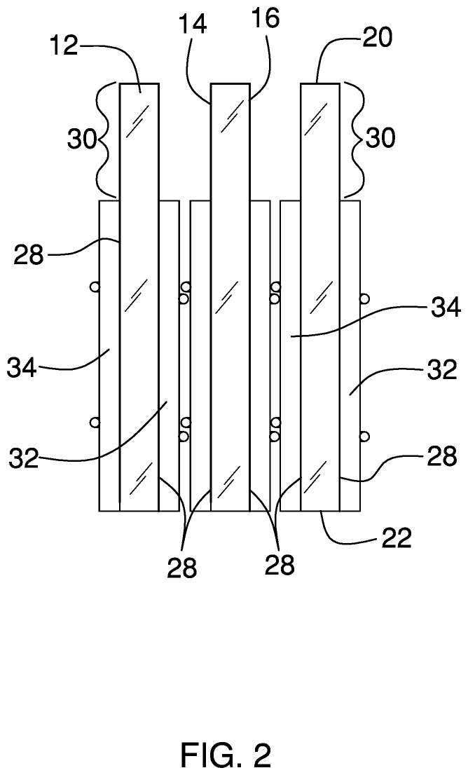

The photovoltaic material 28 and the plate 12 together define a photovoltaic unit. The assembly 10 may include a plurality of the photovoltaic units such that a plurality of the plates 12 and the photovoltaic materials 28 are provided. The photovoltaic units may be positioned adjacent to each other as shown in FIG. 2 such that each of the upper edges 20 are coplanar with each other and each of the upper edges 20 extends along lines spaced from and orientated parallel to each other. Additionally, the lower edges 22 are co-planar with each other, each of the first lateral edges 24 are co-planar with each and each of the second lateral edges 26 are coplanar with each other. The photovoltaic units may be electrically coupled together in series to form a solar collector using conventional electrical connection wires or couplers.

In another embodiment, the assembly 10 includes a first panel 32 and a second panel 34. Each of the first 32 and second 34 panels has a first side 36, a second side 38, and a perimeter edge 40. The perimeter edge 40 includes a first edge 42, a second edge 44, a third edge 46 and a fourth edge 48 wherein the first 42 and second 44 edges are positioned opposite of each other. A first distance is defined from each of the first edges 42 to a corresponding one of the second edges 44 and a second distance is defined from each of the third edges 46 to a corresponding one of the fourth edges 48. The first 32 and second 34 panels are aligned with each other such that first sides 42 of the panels 32, 34 face each other. A receiving space 50 is defined between the first 32 and second 34 panels. The photovoltaic material 28 is positioned on the first side 36 of each of the panels 32, 34 and may be any conventional photovoltaic material as described above.

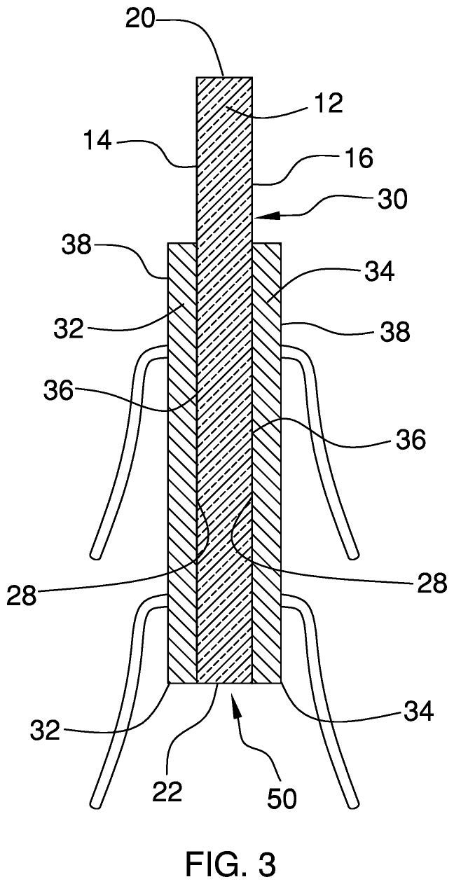

The plate 20 is placed in the receiving space 50 and extends outwardly in at least one direction from the receiving space 50 to define the free portion 30 of the plate 12 as shown in FIG. 3. The plate 12 has a height from the upper edge 20 to the lower edge 22 that is greater than the first distance so that the upper edge 20 of the plate 12 extends outwardly away from the first edges 42 of the panels 32, 34.

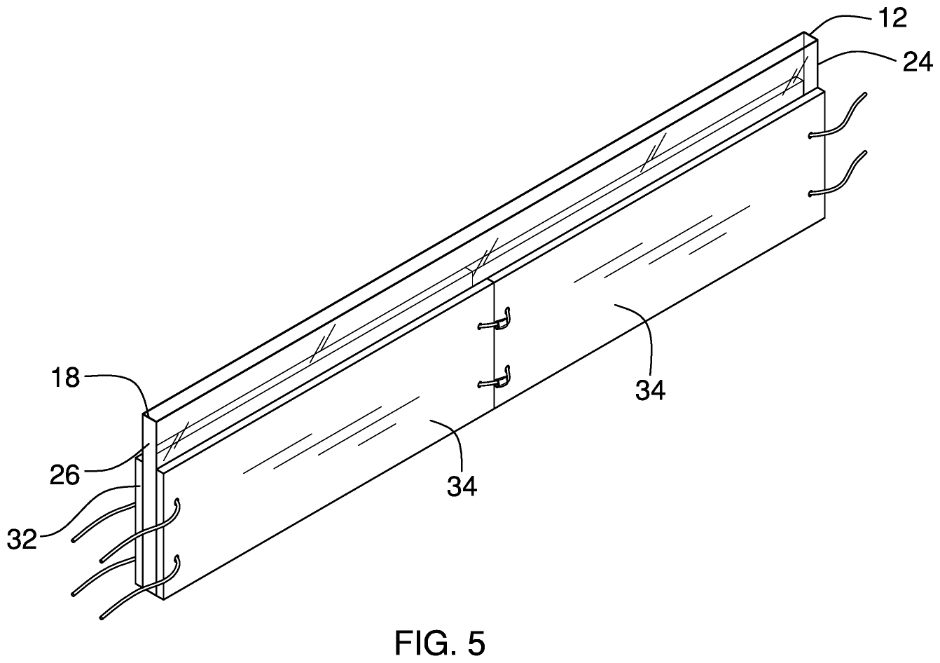

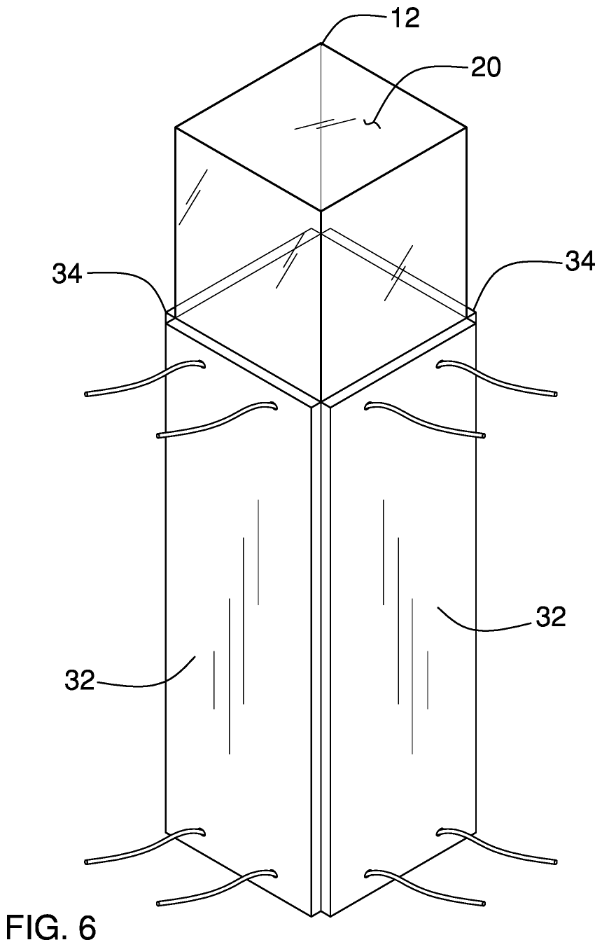

However, it should be understood that variations of the plates 12 and panels 32, 34 may be provided. For example, the plate 12, instead of being elongated from the first lateral edge 24 to the second lateral edge 26, may have first 24 and second 26 lateral edges being wider and perhaps equal to a width of the front 14 and back 16 sides as shown in FIG. 6. This shape would allow panels 32, 34 and photovoltaic material 28 to be positioned on four sides of the plate 12 instead of simply two. Additional plates 12 may be provided as well, such as positioning plates 12 under photovoltaic units 28 to capture any lateral light to direct it upwardly through the lower edges 22 of the plates 12 of the photovoltaic units. Additionally, the plate may be lengthened so that multiple ones of the first 32 and second 34 plates may be utilized as is shown in FIG. 5.

In use, the assembly 10 is utilized as would be conventional photovoltaic cells however the current assembly 10 occupies a smaller footprint while generating more electricity compared to conventional configurations due to the greater area amount of photovoltaic material 28 per surface area covered by the photovoltaic units.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A light directing and photovoltaic material combination assembly, the assembly comprising:
a first panel and a second panel, each of the first and second panels having a first side, a second side, and a perimeter edge, the first and second panels being aligned with each other such that first sides of the panels face each other, a receiving space being defined between the first and second panels;
a photovoltaic material being positioned on the first sides of each of the panels; and
a plate being comprised of a transparent material, the receiving space having the plate positioned therein, the plate extending outwardly in at least one direction from the receiving space to define a free portion of the plate, the free portion being configured to receive light and direct the light into the receiving space such that the light strikes the photovoltaic material.

2. The light directing and photovoltaic material combination assembly according to claim 1, wherein the perimeter edge includes a first edge, a second edge, a third edge and a fourth edge wherein the first and second edges are positioned opposite of each other, a first distance being defined from each of the first edges to a corresponding one of the second edges, a second distance being defined from each of the third edges to a corresponding one of the fourth edges, the first edges being co-planar with respect to each other, the plate having an upper edge, a lower edge, a first lateral edge and a second lateral edge, the plate having a height from the upper edge to the lower edge being greater than the first distance, wherein the upper edge of the plate extends outwardly away from the first edges of the panels.

3. The light directing and photovoltaic material combination assembly according to claim 2, wherein the first panel, the second panel, the photovoltaic material and the plate define a photovoltaic unit, the assembly further including a plurality of the photovoltaic units such that a plurality of the plates, the panels and the photovoltaic materials are provided, the photovoltaic units being positioned adjacent to each other such that each of the first panels of the photovoltaic units bounded by other ones of the photovoltaic units are adjacent to and face one of the second panels.

4. The light directing and photovoltaic material combination assembly according to claim 3, wherein the first edges of each of photovoltaic units are co-planar with each other.

5. The light directing and photovoltaic material combination assembly according to claim 4, wherein the second edges of each of the photovoltaic units are co-planar with each other.

6. The light directing and photovoltaic material combination assembly according to claim 5, wherein the upper edges of the plates of the photovoltaic units are co-planar with each other.

7. The light directing and photovoltaic material combination assembly according to claim 3, wherein the upper edges of the plates of the photovoltaic units are co-planar with each other.

8. The light directing and photovoltaic material combination assembly according to claim 1, wherein the first panel, the second panel, the photovoltaic material and the plate define a photovoltaic unit, the assembly further including a plurality of the photovoltaic units such that a plurality of the plates, the panels and the photovoltaic materials are provided.

9. The light directing and photovoltaic material combination assembly according to claim 8, wherein the photovoltaic units are positioned adjacent to each other such that each of the first panels of the photovoltaic units bounded by other ones of the photovoltaic units are adjacent to and face one of the second panels.

10. A light directing and photovoltaic material combination assembly, the assembly comprising:
a plate being comprised of a transparent material, the plate having a front side, a back side, and a peripheral edge, the peripheral edge including an upper edge and a lower edge;
a photovoltaic material being positioned against each of the front and back sides, the photovoltaic material being spaced from the upper edge on each of the front and back sides to define a free portion of the plate extending from the photovoltaic material to the upper edge; and
the free portion being configured to receive light and direct the light to the photovoltaic material.

11. The light directing and photovoltaic material combination assembly according to claim 10, wherein the photovoltaic material extends to the lower edge of the first and second sides.

12. The light directing and photovoltaic material combination assembly according to claim 11, wherein the peripheral edge includes a first lateral edge and a second lateral edge, the photovoltaic material extending from the first lateral edge to the second lateral edge.

13. The light directing and photovoltaic material combination assembly according to claim 10, wherein the photovoltaic material and the plate define a photovoltaic unit, the assembly further including a plurality of the photovoltaic units such that a plurality of the plates and the photovoltaic materials are provided, the photovoltaic units being positioned adjacent to each other such that each of the upper edges are coplanar with each other and each of the upper edges extends along lines spaced from and orientated parallel to each other.

14. The light directing and photovoltaic material combination assembly according to claim 12, wherein the photovoltaic material and the plate define a photovoltaic unit, the assembly further including a plurality of the photovoltaic units such that a plurality of the plates and the photovoltaic materials are provided, the photovoltaic units being positioned adjacent to each other such that each of the upper edges are coplanar with each other and each of the upper edges extends along lines spaced from and orientated parallel to each other.

15. The light directing and photovoltaic material combination assembly according to claim 14, wherein the lower edges are co-planar with each other, each of the first lateral edges are co-planar with each and each of the second lateral edges are coplanar with each other.
